(19) United States
(12) Patent Application Publication
(10) Pub. No.: US 2026/0068691 A1
(43) Pub. Date: Mar. 5, 2026

(54) Semiconductor Package with Selective Surface Roughening

(71) Applicant: Infineon Technologies Austria AG, Villach (AT)

(72) Inventors: Kah Wei Gan, Bukit Beruang (MY); Jason Nojas Costoya, Batangas (PH); Zhi Yuan Goh, Bertam (MY); Marifi Corregidor Cagud, Muar (MY); Michael Stadler, München (DE)

(21) Appl. No.: 18/817,709

(22) Filed: Aug. 28, 2024

(51) Int. Cl. H01L 23/495; H01L 23/15

(52) U.S. Cl. CPC H01L 23/49503

(57) ABSTRACT

A method of forming a semiconductor package includes providing a metal lead frame comprising a die pad and a plurality of leads, mounting a high-voltage die on an upper surface of the die pad such that a load terminal of the high-voltage die is electrically connected to the die pad, mounting an electrical isolation pad on the die pad, and mounting a low-voltage die on the electrical isolation pad, wherein at least one of: mounting the high-voltage die, mounting the electrical isolation pad, and mounting the low-voltage die includes performing a float-limiting attachment process, wherein the float-limiting attachment process comprises performing a surface roughening process to an attachment surface that forms a border of roughened surface around a mounting area, arranging an attachment material within the mounting area with a mounting element disposed thereon, and liquifying the attachment material with the mounting element disposed thereon.

### TECHNICAL FIELD

The instant application relates to semiconductor devices, and more particularly to semiconductor packages that use liquified attachment materials to mount elements.

### BACKGROUND

Many different applications such as automotive and industrial applications utilize power semiconductor packages. Power semiconductor packages may include power conversion circuits such as single and multi-phase half-wave rectifiers, single and multi-phase full-wave rectifiers, voltage regulators, inverters, etc. Integrated power modules (IPMs), also referred to as intelligent power modules, include both power electronic circuitry and the logic circuitry for controlling operation of the power electronic circuitry. Power semiconductor packages can form part of power efficient solutions to reduce or prevent anthropogenic emissions of greenhouse gases. For instance, hybrid electric vehicles (HEVs) or electric vehicles (EVs) utilize power semiconductor packages to perform power conversion, inversion, switching, etc., in a power efficient manner. In semiconductor packages, many types of attachment solutions exist for affixing a mounting element, e.g., a die, a passive device, an insulating substrate, etc., to a supporting substrate. These attachment solutions include liquid-based attachment materials that are at least temporarily liquified during the attachment process. While advantageous in many respects, these attachment solutions pose challenges because the mounted elements may drift during the attachment process.

### SUMMARY

Those skilled in the art will recognize additional features and advantages upon reading the following detailed description, and upon viewing the accompanying drawings.

A method of forming a semiconductor package is disclosed. According to an embodiment, the method comprises providing a metal lead frame comprising a die pad and a plurality of leads extending away from the die pad, mounting a high-voltage die on an upper surface of the die pad such that a first load terminal of the high-voltage die is electrically connected to the die pad, mounting an electrical isolation pad on the upper surface of the die pad, and mounting a low-voltage die on an upper surface of the electrical isolation pad, wherein at least one of: mounting the high-voltage die, mounting the electrical isolation pad, and mounting the low-voltage die comprises performing a float-limiting attachment process, wherein the float-limiting attachment process comprises performing a surface roughening process to an attachment surface that forms a border of roughened surface at least substantially surrounding a mounting area, arranging an attachment material within the mounting area with a mounting element disposed thereon, and liquifying the attachment material with the mounting element disposed thereon.

A semiconductor package is disclosed. According to an embodiment, the semiconductor package comprises a metal lead frame comprising a die pad and a plurality of leads extending away from the die pad, a high-voltage die mounted on an upper surface of the die pad such that a first load terminal of the high-voltage die is electrically connected to the die pad, and an electrical isolation pad mounted on an upper surface of the die pad, and a low-voltage die mounted on an upper surface of the electrical isolation pad, wherein the semiconductor package comprises one or more mounting areas on an attachment surface that is at least substantially surrounded by a border of roughened surface, and wherein at least one of the high-voltage die, the electrical isolation pad, and the low-voltage die is mounted by an attachment material within one of the mounting areas.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A, 1B, 1C and 1D, illustrates selected steps from a float-limiting attachment process, according to an embodiment.

FIG. 2 illustrates a package assembly, according to an embodiment.

FIG. 3, which includes FIGS. 3A and 3B, illustrates selected steps in a method for forming the package assembly using a float-limiting attachment process, according to an embodiment.

### DETAILED DESCRIPTION

Embodiments of a semiconductor package formation technique and corresponding semiconductor package are described herein. The semiconductor package comprises a high-voltage die and a low-voltage die mounted together on a common die pad of a lead frame. The high-voltage die is mounted directly on the die pad. The die pad can be configured as a high voltage plane that connects with a load terminal of the high-voltage die. The low-voltage die is mounted with an electrical isolation pad interposed between the die and the die pad, thereby providing electrical isolation between the two. At least one of the electrical isolation pad, the low-voltage die, and the high-voltage die is mounted by a float-limiting attachment process. The float-limiting attachment process is used in combination with a liquifiable adhesive. The float-limiting attachment process comprises creating a border of roughened surface area around a mounting area that accommodates the liquifiable adhesive. The border of roughened surface area impedes flow of the attachment material in its liquified state and restricts movement of the mounted component thereon. Consequently, the mounted element is less prone to lateral and/or rotational movement from the attachment process. This ensures that electrical interconnections such as bond wires can be formed without misalignment issues.

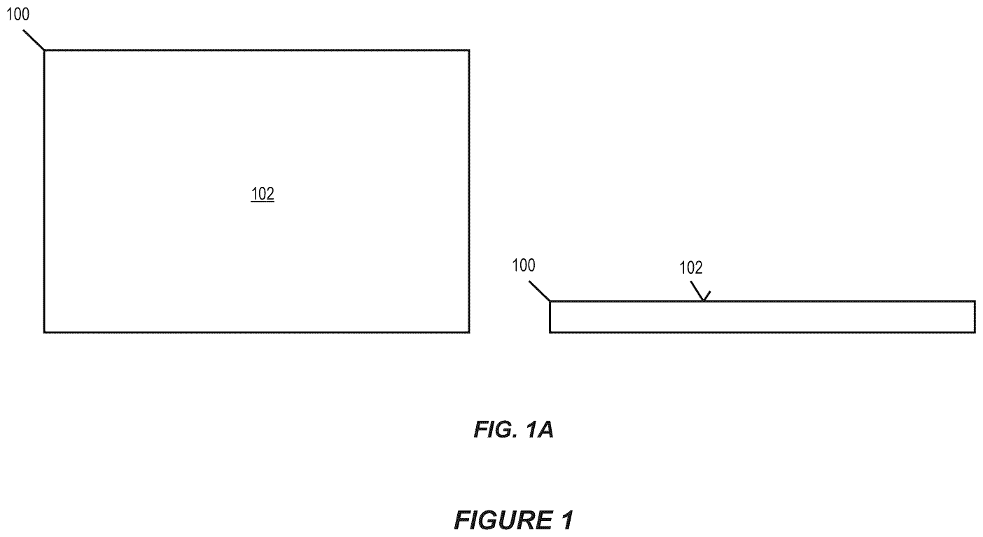

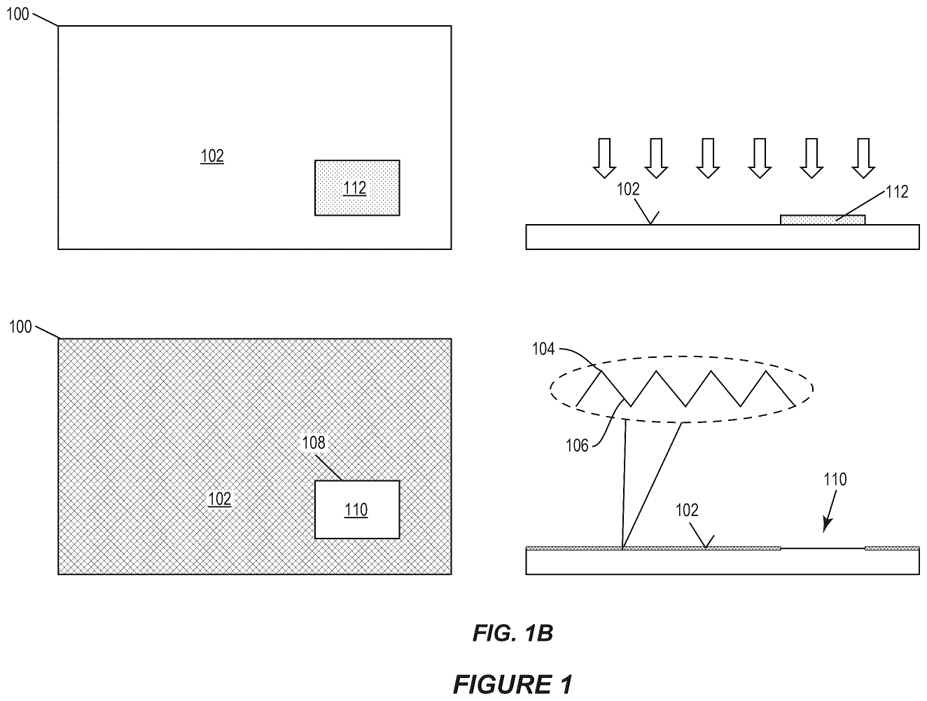

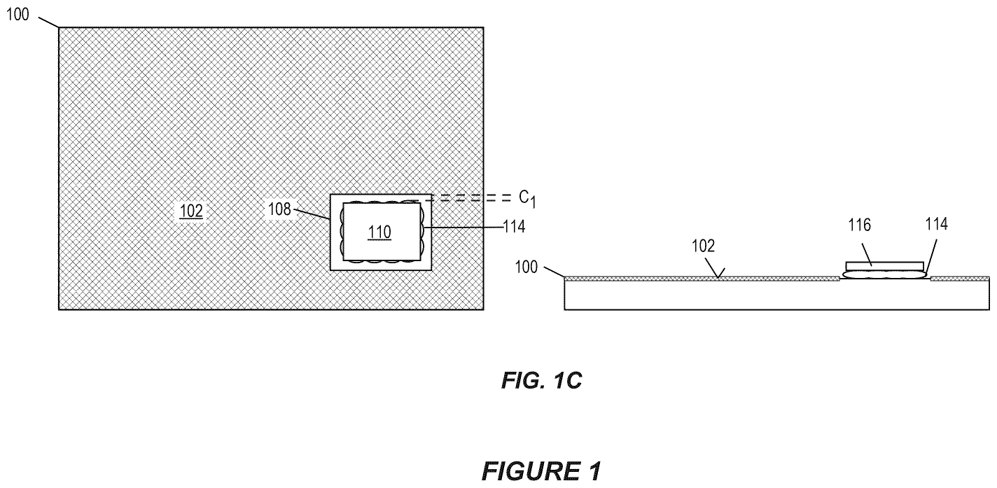

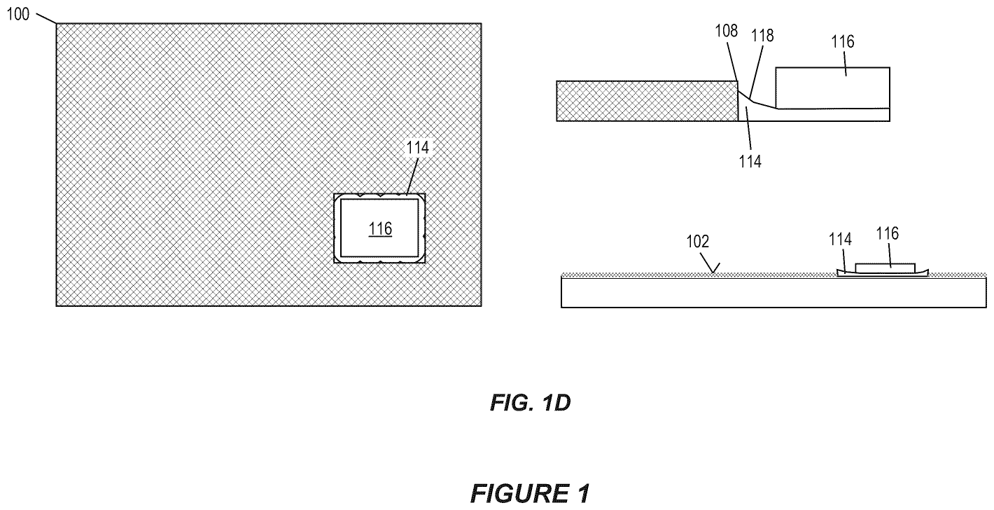

Referring to FIG. 1A, a float-limiting attachment process comprises providing a carrier 100. The carrier 100 can be any type of substrate that accommodates the mounting of one or more electronics components. The carrier 100 can comprise metal, e.g., Cu, Ni, Ag, Au, Pd, Pt, Ni, and alloys or combinations thereof. Separately or in combination, the carrier 100 can comprise an electrically insulating material, e.g., glass materials, fiberglass materials, ceramic materials, polymer materials, etc. In an embodiment, the carrier 100 is a completely metal structure. In an example of this, the carrier 100 may be a die pad from a metal lead frame. In another embodiment, the carrier 100 comprises a combination of metal and electrically insulating material. In an example of this, the carrier 100 may be an insulated electronics carrier such as a PCB (printed circuit board), a DBC (direct bonded copper) substrate, an IMS (insulated substrate) substrate or an AMB (active metal brazed) substrate, etc. In an embodiment, the carrier 100 is a completely electrically insulating structure. In an example of this, the carrier 100 may be an electrical isolation pad that is used to electrically isolate a component mounted on the carrier 100 from a subjacent electrically conductive surface. In that case, the carrier 100 may be a glass substrate formed of glass materials, e.g., quartz glass, silica glass, soda lime glass, etc.

The carrier 100 comprises an attachment surface 102. The attachment surface 102 is a planar surface that is configured to accommodate the mounting of one or more electronics components, e.g., semiconductor dies, passive components, electrical interconnect elements, etc., thereon. The attachment surface 102 may corresponds to an entire upper surface of the carrier 100, e.g., in the case of a die pad or an electrical isolation pad. Alternatively, the attachment surface 102 may correspond to a portion of the upper surface of the carrier 100, e.g., in the case of an insulated electronics carrier with structured metal pads. At this stage, the attachment surface 102 is a smooth surface. In the context of the instant description, this means that the attachment surface 102 has an Rₐ value, which refers to the average deviation between all peaks and valleys on the attachment surface 102, of no more than 5 μm and/or has an Rz value, which refers to the difference between the highest peak and the lowest valley on the attachment surface 102, of no more than 10 μm.

Referring to FIG. 1B, the float-limiting attachment process comprises performing a surface roughening process to the attachment surface 102 of the carrier 100. The surface roughening process creates an intentionally roughened pattern in the attachment surface 102. As shown in the magnified view of the attachment surface 102, the roughened surface is formed by projections and recesses, with apexes 104 that correspond to the high points of the projections and nadirs 106 that correspond to the low points in between the projections. The figure generally illustrates the roughened surface while not necessarily accurately depicting the precise contours of the roughening. In practice, the geometry of the projections, the height of the projections relative to one another, distance between the projections, etc., may differ from what is shown. For example, the projections may have arbitrary shapes, multi-angled shapes, partially curved shapes, etc. Moreover, the projections may vary in shape from one another across the same surface. Separately or in combination, the height of the apexes 104 and/or adjoining nadirs 106 may vary within a range of values. Separately or in combination, the separation distance between apexes 104 and/or nadirs 106 may vary within a range of values. The topology of the roughened surface may depend on the type of roughening process used.

The surface roughening process forms a border 108 of the roughened surface. The border 108 of the roughened surface at least substantially surrounds a mounting area 110. That is, the roughened surface has defined edge sides that form an enclosed shape or a nearly enclosed shape around a mounting area 110 that is devoid of the roughened surface. The mounting area 110 thus retains the smooth properties of the attachment surface 102 of the carrier 100 prior to the surface roughening. As used herein, the description that the border 108 of the roughened surface at least substantially surrounds the mounting area 110 allows for small interruptions or outlets in the border 108. For example, the border 108 of the roughened surface may surround at least 90% of the mounting area 110, with interruptions in the remaining parts of the border 108. Provided that the border 108 of the roughened surface can create meniscuses in an attachment material and substantially restrict movement of a mounted component in the manner described herein, it substantially surrounds the mounting area 110 within the meaning of the present description. In the depicted embodiment, the border 108 of roughened surface forms an enclosed shape that completely surrounds the mounting area 110. More particularly, this enclosed shape is rectangular. The particular shape of the border 108 may be selected to mimic that of the component footprint and/or adhesive material footprint to be mounted within the mounting area 110.

According to the depicted embodiment, the surface roughening process comprises a masked etching technique. According to this technique, a structured mask 112 is provided on the attachment surface 102. The geometry of the structured mask 112 corresponds to the desired geometry of the mounting area 110 to be formed within the roughened surface pattern. The structured mask 112 can be formed of any materials that resist the subsequent etching process to protect the attachment surface 102 of the carrier 100. For example, the structured mask 112 can comprise an adhesive layer and/or a hard material structure that is adhesively bonded to the attachment surface 102 of the carrier 100. Subsequently, an etching process is performed that roughens the attachment surface 102 outside of the structured mask 112, thereby defining the border 108 of roughened surface around the mounting area 110. In general, the etching process can be any process that damages the attachment surface 102 of the carrier 100 to create a pattern of apexes 104 and nadirs 106 in the attachment surface 102 that vertically deviate from one another. According to an embodiment, the etching process comprises a wet chemical etching process. Optionally, this wet chemical etching may comprise an electrochemical process that involves an electrolytic bath. Once the etching process is complete, the mask can be removed, thereby exposing the mounting area 110. Instead of a chemical etching technique, any of a variety of other roughening techniques may be performed to create the roughened pattern in the attachment surface 102 of the carrier 100. Examples of these roughening techniques include mechanical roughening techniques, e.g., polishing, grinding, laser patterning techniques, etc.

The degree of the surface roughening is selected to create a barrier that impedes the flow of liquified attachment material and creates a meniscus effect, as will be described in further detail below. The following exemplary values represent sufficient surface roughening to create this meniscus effect with the liquified attachment material and components described herein. According to an embodiment, the Ra value of the roughened surface is between 10 μm and 100 μm, more particularly may be between 15 μm and 75 μm, and more particularly may be between 20 μm and 40 μm. In specific embodiments, the Ra value of the roughened surface is at least 15 μm, at least 16 μm, at least 17 μm, at least 18 μm, at least 19 μm, or at least 20 μm. Separately or in combination, the Rz value of the roughened surface is between 15 μm and 150 μm, more particularly may be between 20 μm and 75 μm, and more particularly may be between 25 μm and 50 μm. In specific embodiments, the Rz value of the roughened surface is at least 18 μm, at least 19 μm, at least 20 μm, at least 21 μm, at least 22 μm, or at least 23 μm. Separately or in combination, the Ra value of the roughened surface and/or the Rz value of the of the roughened surface may be at least 100%, at least 200%, at least 300%, at least 400%, or at least 500% greater than the smooth surface prior to the surface roughening process.

As shown, the surface roughening process is performed to the entire attachment surface 102 outside of the mounting area 110. As a result, the roughened surface is present throughout the attachment surface 102 except for the mounting area 110. In other embodiments, the surface roughening process may be performed only on a portion of the carrier 100. For example, the surface roughening process may form a discrete frame shape that surrounds the mounting area 110, with the remaining part of the attachment surface 102 outside of this frame shape retaining the original substantially smooth surface.

Referring to FIG. 1C, the float-limiting attachment process comprises arranging an attachment material 114 within the mounting area 110. Generally speaking, the attachment material 114 can be any material that can form an adhesive connection between two elements, wherein the attachment material 114 can be liquified, either at room temperature or at higher temperatures, and subsequently hardened to form an adhesive connection between. According to an embodiment, the attachment material 114 is an electrically insulating adhesive, such as a glue material. More particularly, the attachment material 114 may be a curable adhesive that can be liquified and subsequently hardened by a curing process. According to an embodiment, the attachment material 114 is an electrically conductive material. For example, the attachment material 114 may be a solder material comprising, e.g., SnSb, SnCu, SnAg, etc., that is liquified and subsequently hardened by a reflow process.

The attachment material 114 is arranged within the mounting area 110 with a mounting element 116 disposed thereon. The attachment material 114 may be initially provided on either the carrier 100, the mounting element 116, or both. The mounting element 116 may be an active semiconductor element, a passive component, or a further carrier 100 structure. For example, the mounting element 116 may be a semiconductor die. In one particular embodiment, the mounting element 116 is a vertical semiconductor device and the attachment material 114 is a solder material that is used to provide an electrical connection between a lower surface terminal of the semiconductor die and the carrier 100. In another embodiment, the mounting element 116 is a lateral device and the attachment material 114 is an adhesive material, such as a die attach material. In another embodiment, the mounting element 116 is an electrically insulating structure, such as an electrical isolation pad. In an example of this, the carrier 100 may be a glass substrate formed of glass materials, e.g., quartz glass, silica glass, soda lime glass, etc.

Referring to FIG. 1D, the attachment material 114 is liquefied with the mounting element 116 disposed thereon. As used herein, a liquid material refers to a material with a viscosity of 10,000 mPa·s (roughly that of Honey) or less. In an embodiment, the liquification may be brought about through the application of heat. For example, in the case of an attachment material 114 that is a curable adhesive, the attachment material 114 may be elevated to a temperature that induces a cross-linking reaction, e.g., temperatures on the order of 100° C., 125° C., 150° C. or more. In the case of an attachment material 114 that is a solder material, a temperature of the attachment material 114 may be elevated to a reflow temperature of the material, e.g., temperatures on the order of 200° C., 250° C., 300° C. or more. In another embodiment, the attachment material 114 is initially applied as a liquid at room temperature and is subsequently hardened through the use of agents.

As shown, the liquified attachment material 114 flows outward from the center of the mounting area 110. The liquified attachment material 114 reaches the border 108 and interacts with the roughened surface, which impedes further flow of the attachment material 114. That is, the roughened surface presents a barrier that resists flow of the liquified material to a much greater degree than the relatively smooth unroughened surface of the carrier 100, due to surface tension effects. As a result, a meniscus 118 forms between the border 108 of roughened surface and the mounting element 116. With the attachment material 114 having the meniscus 118, the movement of the mounting element 116 is impeded. That is, the mounting element 116 is prevented from floating freely over the liquified attachment material 114. In this way, the position of the mounting element 116 is maintained substantially close to its original location in comparison to a technique that does not utilize surface roughening with a border 108 of roughened surface as disclosed herein. In this context, the description that the position of the mounting element 116 is maintained substantially close to its original location refers to both linear movements in which a centroid of the mounting element 116 drifts from its original location and rotational movements in which the mounting element 116 rotates about an axis.

Referring again to FIG. 1C, the float-limiting attachment process is performed such that a clearance C₁ exists between the attachment material 114 and the border 108 in every direction surface before liquifying the attachment material 114. The amount of clearance C₁ is selected to provide enough margin for the precise application of the attachment material 114 and mounting of the mounting element 116 without bleed-over and to facilitate lateral expansion of the attachment material 114 in every direction to create the meniscus 118 as described above. However, the separation distance between the attachment material 114 and the border 108 of should remain sufficiently low to ensure that the position of the mounting element 116 is sufficiently restrained by the meniscus 118 during the liquification process. Generally speaking, the clearance C₁ between the attachment material 114 and the border 108 may be between 150 μm and 300 μm to meet these criteria. According to an embodiment, a minimum value of the clearance C₁ between the attachment material 114 and the border 108 of roughened surface is at least 100 μm, at least 150 μm, at least 175 μm, at least 200 μm, at least 225 μm, or at least 250 μm, wherein the minimum value of the clearance C₁ refers to the distance between the attachment material 114 at its closest point to the border 108 of roughened surface. Separately or in combination, a maximum value of the clearance C₁ may be between the attachment material 114 and the border 108 may be no greater than 300 μm, no greater than 275 μm, no greater than 250 μm, no greater than 225 μm, or no greater than 200 μm, wherein the maximum clearance refers to the distance between the attachment material 114 at its furthest point to the border 108 of roughened surface.

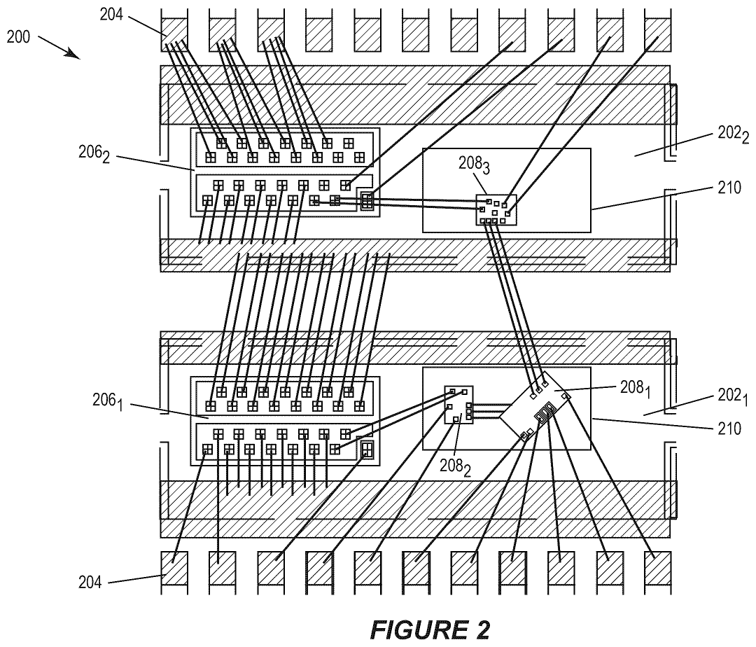

Referring to FIG. 2, a semiconductor package assembly 200 is shown, according to an embodiment. The semiconductor package comprises a metal lead frame comprising die pads 202 and a plurality of leads 204 extending away from the die pads. As depicted, the metal lead frame comprises a first one 202₁ of the die pads 202 and a second one 202₂ of the die pads separate from the first one 202₁. During assembly, the semiconductor package assembly 200 may comprise a peripheral structure (not shown) that is physically connected to the leads 204 and supports the die pads 202 via tie-bars. The lead frame is formed from an electrically conductive metal, such as copper, nickel, aluminum, palladium, gold, and alloys or combinations thereof. The lead frame can be provided from a substantially uniform thickness sheet of metal and the geometric features of the lead frame can be created by metal processing techniques, e.g., stamping, punching, etching, etc.

The semiconductor package assembly 200 comprises high-voltage dies 206. A high-voltage die 206 refers to a device that is rated to control voltages associated with power applications, e.g., voltages of at least 100 V (volts), and more typically voltages of 600 V, 1200 V or more and/or currents of least 1A, and more typically currents of 10A, 50A, 100A or more. The high-voltage dies 206 each comprise a first load terminal and a second load terminal. The load terminals refer to the terminals that are configured to the rated voltage, e.g., source and drain terminals, collector and emitter terminals, anode and cathode terminals, etc.

As shown, the semiconductor package assembly 200 comprises a first one 206₁ of the high-voltage dies 206 mounted on the first one 202₁ of the die pads 202 and a second one 206₂ of the high-voltage dies 206 mounted on the second one 202₂ of the die pads 202. The first one 206₁ of the high-voltage dies 206 and the second one 206₂ of the high-voltage dies 206 are configured as discrete transistor dies, e.g., MOSFETs (Metal Oxide Semiconductor Field Effect Transistors), IGBTs (Insulated Gate Bipolar Transistors), and HEMTs (High Electron Mobility Transistors). The first one 206₁ of the high-voltage dies 206 and the second one 206₂ of the high-voltage dies 206 are configured such that the first load terminal of these devices is disposed on a lower side of the die, and the second load terminal and the gate terminal of these devices are disposed on an upper side of the semiconductor die. The first load terminal of the first one 206₁ of the high-voltage dies 206 may be directly electrically connected with the first one 202₁ of the die pads 202 by an electrically conductive solder material. Correspondingly, the first load terminal of the second one 206₂ of the high-voltage dies may be directly electrically connected with the second one 202₂ of the die pads 202 by an electrically conductive solder material.

The semiconductor package assembly 200 additionally comprises a plurality of low-voltage dies 208. In comparison to the high-voltage dies 206, the low-voltage dies 208 have a much lower voltage rating than the high-voltage dies 206. For example, the low-voltage dies 208 may operate at voltages below 15 V, below 10 V, below 5 V, etc. The low-voltage dies 208 may be silicon-based logic dies, for example.

As shown, the semiconductor package assembly 200 comprises a first one 208₁ of the low-voltage dies 208 and a second one 208₂ of the low-voltage dies 208 mounted on the first one 202₁ of the die pads 202 and comprises a third one 208₃ of the low-voltage dies 208 mounted on the second one 202₂ of the die pads 202. The second one 208₂ of the low-voltage dies 208 may be a driver die configured to control a switching operation of the first one 206₁ of the high-voltage dies 206, the third one 208₃ of the low-voltage dies 208 may be a driver die configured to control a switching operation of the second one 206₂ of the high-voltage dies 206, and the first one 208₁ of the low-voltage dies 208 may be controller device configured to control the second one 208₂ of the low-voltage dies 208 and the third one 208₃ of the low-voltage dies 208.

The semiconductor package assembly 200 comprises electrical isolation pads 210 interposed between the low-voltage dies 208 and the die pads 202, thereby providing electrical isolation between the two. The electrical isolation pads 210 comprise a dielectric material with sufficient dielectric strength to maintain electrical isolation between the voltage plane of the die pads. According to an embodiment, the electrical isolation pads 210 are glass substrates formed of or comprising quartz glass, silica glass, soda lime glass, etc. A thickness of the electrical isolation pads 210 may be between 100 μm and 1,000 μm, for example. The electrical isolation pads 210 are mounted on the die pads 202 by an attachment material 114. According to an embodiment, the attachment material 114 used to mount the electrical isolation pads 210 is curable adhesive that can be liquified and hardened by a curing process. Likewise, the low-voltage dies 208 are mounted on the electrical isolation pads 210 by an attachment material 114. According to an embodiment, the attachment material 114 used to mount the low-voltage dies 208 on the electrical isolation pads 210 is curable adhesive that can be liquified and hardened by a curing process.

The semiconductor package assembly 200 comprises electrical interconnect elements that form electrical interconnections between the semiconductor dies and the lead frame. These electrical interconnections include power connections between the second load terminals of the high-voltage dies 206 and the leads 204, gate connections between the gate terminals of the high-voltage dies 206 and the low-voltage dies 208, I/O connections between two of the low-voltage dies 208, and I/O connections between the low-voltage dies 208 and the leads 204. In the depicted embodiment, each of the electrical interconnections are provided by bond wires. In other embodiments, at least some of these electrical interconnections are provided by other types of electrical interconnect elements.

According to an embodiment, the semiconductor package assembly 200 is configured as an integrated half-bridge circuit. A half-bridge circuit refers to one type of circuit topology that is used in a power conversion circuit, such as a DC to DC converter, DC to AC converter, etc. A half-bridge circuit comprises a high-side switch connected in series with a low-side switch, wherein the high-side switch and a low-side switch are operated according to a power control scheme e.g., pulse width modulation, to produce a desired voltage and frequency at the output of the half-bridge circuit. According to an embodiment, the first one 206₁ of the high-voltage dies 206 corresponds to the high-side switch and the second one 206₂ of the high-voltage dies 206 corresponds to the low-side switch, the second one 208₂ of the low-voltage dies 208 and the third one 208₃ of the low-voltage dies 208 correspond to driver dies that are configured to control a switching operation of the high-side switch and the low-side switch, respectively, and the third one 208₃ of the low-voltage dies 208 corresponds to a controller die that is control the operation of the half-bridge circuit.

According to an embodiment, at least one of: the mounting of the high-voltage dies 206, the mounting electrical isolation pads 210, and the mounting of the low-voltage dies 208 is performed by the float-limiting attachment process as described herein. In the case of the high-voltage dies 206 being mounted by the float-limiting attachment process, the carrier 100 corresponds to the die pad 202 and the attachment material 114 corresponds to the solder material provided between the high-voltage dies 206 and the die pad 202. In the case of the electrical isolation pads 210 being mounted by the float-limiting attachment process, the carrier 100 corresponds to the die pad 202 and the attachment material 114 corresponds to the adhesive provided between the electrical isolation pads 210 and the die pad. In the case of the low-voltage dies 208 being mounted by the float-limiting attachment process, the carrier 100 corresponds to the electrical isolation pads 210 and the attachment material 114 corresponds to the adhesive provided between the low-voltage dies 208 and the electrical isolation pads 210.

By performing the float-limiting attachment process on the mountable elements of the semiconductor package, the electrical interconnect process can be performed more reliably without having to discard parts. As can be appreciated from FIG. 2, the wiring of the semiconductor package involves many different routings. These electrical interconnections are typically performed by automated machinery that makes the connections dependent on the semiconductor dies being mounted in an expected location. If these devices drift away from their expected location because they temporarily float on top of a liquified material during the attachment process, this may lead to missed connections and/or crisscrossing of bond wires. Particularly with respect to the low-voltage dies 208 mounted on the electrical isolation pads 210, this effect is compounded, as both the mounting of the electrical isolation pads 210 on the lead frames and the mounting of the low-voltage dies 208 thereon present an opportunity for movement. As explained above, the float-limiting attachment process advantageously mitigates the lateral and rotational displacements of the mounted elements. Accordingly, the bond pads of the low-voltage dies 208 and/or the high-voltage dies 206 are more likely to be in their target locations and the electrical interconnect process can be performed without failure.

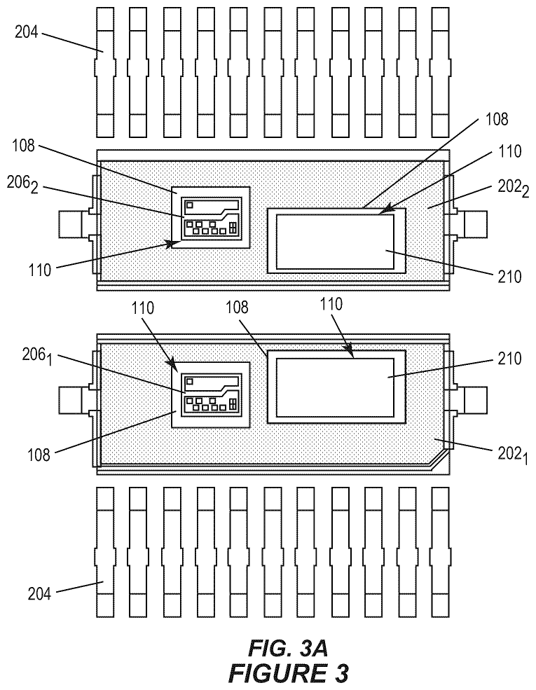

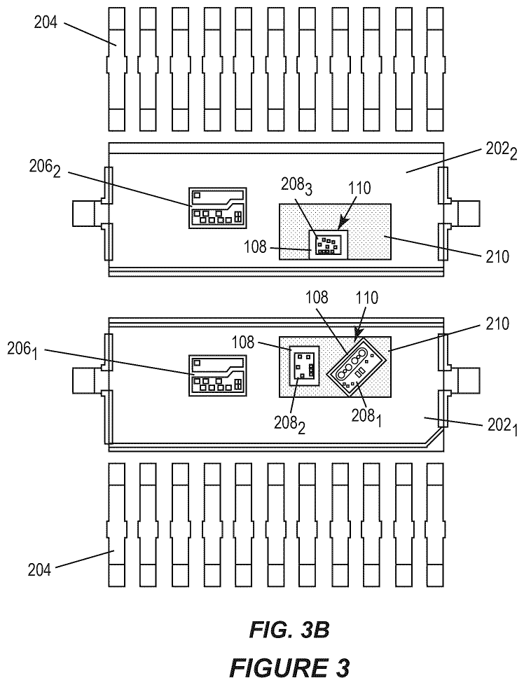

After forming the semiconductor assembly shown in FIG. 3, a completed semiconductor package may be formed by forming an electrically insulating encapsulant body that encapsulates each of the semiconductor dies, while leaving portions of the leads exposed from the encapsulant body. The encapsulant body can be formed by a molding process such as injection molding, transfer molding, compression molding, etc. According to these techniques, the lead frame assembly comprising the semiconductor dies mounting thereon is arranged into a molding tool, the mold compound is injected into the molding tool and is subsequently cured to form the encapsulant body. Generally speaking, the mold compound can comprise dielectric materials such as epoxy, thermosetting plastic, polymer, resin, etc.

Referring to FIG. 3, exemplary methods for forming the semiconductor package assembly 200 using the float-limiting attachment process are shown.

In FIG. 3A, the surface roughening process is performed on the upper surface of the die pads 202. The surface roughening process is performed to create the borders 108 of roughened surface surrounding a mounting area 110 associated with each one of the high-voltage dies 206. The high-voltage dies 206 are mounted within the mounting areas 110 with solder material disposed between the high-voltage dies 206 and the die pads 202. Subsequently, a solder reflow process is performed. The solder reflow liquifies the solder material and interacts with the borders 108 of roughened surface so as to restrain the movement of the high-voltage dies 206. The surface roughening process is additionally performed to form the borders 108 of roughened surface surrounding a mounting area 110 associated with each of the electrical isolation pads 210. The electrical isolation pads 210 are mounted within these mounting areas with adhesive material disposed between the electrical isolation pads 210 and the die pads 202. Subsequently, an adhesive curing process is performed. The adhesive curing process liquefies the attachment material, and interacts with the borders 108 of roughened surface so as to restrain the movement of the high-voltage dies 206.

According to an embodiment, the clearance between the elements mounted on the die pads 202 and the borders 108 of roughened surface is between 225 μm and 275 μm. In a more particular embodiment, this clearance is about 250 μm. The inventors have identified that these clearance values adequately constrain the movement of the mountable elements.

In FIG. 3B, the surface roughening process is performed on the upper surface of the electrical isolation pads 210. The surface roughening process is performed to create the borders 108 of roughened surface surrounding a mounting area 110 associated with each one of the low voltage dies 208. The low voltage dies 208 are mounted within the mounting areas 110 with adhesive material disposed between the low voltage dies 208 and the electrical isolation pads 210. Subsequently, an adhesive curing process is performed. The adhesive curing process liquefies the attachment material and interacts with the borders 108 of roughened surface so as to restrain the low voltage dies 208.

According to an embodiment, the clearance between the elements mounted on the die pads 202 and the borders 108 of roughened surface is between 175 μm and least 225 μm. In a more particular embodiment, this clearance is about 200 μm. The inventors have identified that these clearance values adequately constrain the movement of the low voltage dies 208.

In an embodiment, the processes shown in FIG. 3A and FIG. 3B may be combined with one another. In this way, each of the mounting of the high-voltage dies 206, the mounting electrical isolation pads 210, and the mounting of the low-voltage dies 208 is performed by the float-limiting attachment process as described herein.

Embodiments disclosed herein describe semiconductor devices, which may be referred to a semiconductor chip or semiconductor die. These semiconductor devices can comprise any of a wide variety of semiconductor materials including but not limited to elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum. These semiconductor devices can have a wide variety of device configurations including integrated device configurations and discrete device configurations. These semiconductor devices may be configured as a vertical device, which refers to a device that conducts a load current between opposite facing main and rear surfaces of the die. Alternatively, these semiconductor devices may be configured as a lateral device, which refers to a device that conducts a load current parallel to a main surface of the die.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a semiconductor package, the method comprising:
providing a metal lead frame comprising a die pad and a plurality of leads extending away from the die pad;
mounting a high-voltage die on an upper surface of the die pad such that a first load terminal of the high-voltage die is electrically connected to the die pad;
mounting an electrical isolation pad on the upper surface of the die pad; and
mounting a low-voltage die on an upper surface of the electrical isolation pad;
wherein at least one of: mounting the high-voltage die, mounting the electrical isolation pad, and mounting the low-voltage die comprises performing a float-limiting attachment process,
wherein the float-limiting attachment process comprises:
performing a surface roughening process to an attachment surface that forms a border of roughened surface at least substantially surrounding a mounting area;
arranging an attachment material within the mounting area with a mounting element disposed thereon; and
liquifying the attachment material with the mounting element disposed thereon.

2. The method of claim 1, wherein the float-limiting attachment process is performed such that a clearance exists between the mounting element and a of roughened surface.

3. The method of claim 2, wherein the clearance is between 150 μm and 300 μm.

4. The method of claim 3, wherein the clearance is between about 200 μm and about 250 μm.

5. The method of claim 1, wherein liquifying the attachment material creates a meniscus that extends from the border of roughened surface, wherein the meniscus restricts floating movement of the mounting element.

6. The method of claim 1, wherein the border of roughened surface forms an enclosed shape that completely surrounds the mounting area.

7. The method of claim 1, wherein the surface roughening process comprises:
providing a structured mask on the attachment surface;
performing an etching process that roughens the attachment surface outside of the structured mask, thereby defining the border of roughened surface around the mounting area.

8. The method of claim 1, wherein mounting the electrical isolation pad comprises performing the float-limiting attachment process, wherein the surface roughening process in the mounting the electrical isolation pad is performed on the upper surface of the die pad.

9. The method of claim 8, wherein the mounting of the low-voltage die comprises performing the float-limiting attachment process, wherein the surface roughening process in the mounting of the low-voltage die is performed on the upper surface of the electrical isolation pad.

10. The method of claim 9, wherein the attachment material used in each of the mounting of the electrical isolation pad and the low-voltage die and is an adhesive, and wherein liquifying the attachment material in each of the mounting of the electrical isolation pad and the low-voltage die comprises curing the adhesive.

11. The method of claim 8, wherein the mounting of the high-voltage die comprises performing the float-limiting attachment process, wherein the surface roughening process in the mounting of the high-voltage die is the same surface roughening process that is used in the mounting the electrical isolation pad.

12. The method of claim 1, further comprising performing a wire bonding process after performing the float-limiting attachment process, wherein the wire bonding process comprises forming at least one bond wire connection between the high-voltage die and the low-voltage die.

13. A semiconductor package, comprising:
a metal lead frame comprising a die pad and a plurality of leads extending away from the die pad;
a high-voltage die mounted on an upper surface of the die pad such that a first load terminal of the high-voltage die is electrically connected to the die pad; and
an electrical isolation pad mounted on an upper surface of the die pad; and
a low-voltage die mounted on an upper surface of the electrical isolation pad;
wherein the semiconductor package comprises one or more mounting areas on an attachment surface that is at least substantially surrounded by a border of roughened surface, and
wherein at least one of the high-voltage die, the electrical isolation pad, and the low-voltage die is mounted by an attachment material within one of the mounting areas.

14. The semiconductor package of claim 13, wherein the one or more mounting areas are completely surrounded by the border of roughened surface.

15. The semiconductor package of claim 13, wherein the one or more mounting areas comprise a first mounting area that the electrical isolation pad is disposed within, wherein the attachment surface comprising the border of roughened surface substantially surrounding the first mounting area is the upper surface of the die pad.

16. The semiconductor package of claim 15, wherein the one or more mounting areas comprise a second mounting area that the low-voltage die is disposed within, wherein the attachment surface comprising the border of roughened surface substantially surrounding the second mounting area is the upper surface of the electrical isolation pad.

17. The semiconductor package of claim 16, wherein the one or more mounting areas comprise a third mounting area that the high-voltage die is disposed within, wherein the attachment surface comprising the border of roughened surface substantially surrounding the second mounting area is the upper surface of the electrical isolation pad.

18. The semiconductor package of claim 13, wherein the electrical isolation pad is a glass substrate.

19. The semiconductor package of claim 13, further comprising at least one bond wire connection between the high-voltage die and the low-voltage die.

20. The semiconductor package of claim 13, wherein the high-voltage die is arranged as a switching device in a half-bridge circuit, and wherein the low-voltage die is a driver die that is configured to control a switching operation of the half-bridge circuit.
